(19) United States
(12) Patent Application Publication
(10) Pub. No.: US 2024/0258202 A1
(43) Pub. Date: Aug. 1, 2024

(54) SEMICONDUCTOR DEVICE AND VIBRATOR DEVICE

(71) Applicant: SEIKO EPSON CORPORATION, Tokyo (JP)

(72) Inventor: Yusuke Matsuzawa, Chino-shi (JP)

(21) Appl. No.: 18/423,509

(22) Filed: Jan. 26, 2024

(30) Foreign Application Priority Data
Jan. 30, 2023 (JP) 2023-011719

(51) Int. Cl. H01L 23/48; H01L 21/02; H03H 9/05

(52) U.S. Cl. CPC H01L 23/481; H01L 21/02118; H03H 9/0552

(57) ABSTRACT

A semiconductor device includes a semiconductor substrate including a first surface and a second surface and having a first through hole, a first insulating layer placed on the first surface, including a fourth surface, and having a second through hole, a second insulating layer placed on the second surface and having a first opening portion, a first conducting layer exposed from the second insulating layer by the first opening portion, an organic insulating layer placed on the fourth surface, a side surface of the second through hole, a side surface of the first through hole, a side surface of the first opening portion, and a surface of the first conducting layer, and a second conducting layer placed on a surface of the organic insulating layer and a surface of the first conducting layer, wherein the side surface of the second through hole is a first tapered surface.

The present application is based on, and claims priority from JP Application Serial Number 2023-011719, filed Jan. 30, 2023, the disclosure of which is hereby incorporated by reference herein in its entirety.

### BACKGROUND

### 1. Technical Field

The present disclosure relates to a semiconductor device and a vibrator device.

### 2. Related Art

JP-A-2018-113466 discloses a semiconductor device in which, to prevent leakage between a semiconductor substrate and a conducting layer in a through electrode penetrating the semiconductor substrate, an organic insulating layer covering an insulating layer formed on an inner wall of the through hole is formed and the conducting layer is formed on the organic insulating layer.

However, in the semiconductor device disclosed in JP-A-2018-113466, the organic insulating layer is formed by application of a solution containing an organic insulating material, and a thickness of the organic insulating layer may be thinner in a corner portion of the through hole.

### SUMMARY

A semiconductor device according to an aspect of the present disclosure includes a semiconductor substrate including a first surface and a second surface having a front-back relation to the first surface, and having a first through hole formed to penetrate from the first surface to the second surface, a first insulating layer placed on the first surface, including a third surface at the semiconductor substrate side and a fourth surface having a front-back relation to the third surface, and having a second through hole formed in a position overlapping with the first through hole, a second insulating layer placed on the second surface and having a first opening portion formed in a position overlapping with the first through hole, a first conducting layer exposed from the second insulating layer by the first opening portion, an organic insulating layer placed on the fourth surface, a side surface of the second through hole, a side surface of the first through hole, a side surface of the first opening portion, and a surface of the first conducting layer, and having a second opening portion formed to overlap with the first opening portion, and a second conducting layer placed on a surface of the organic insulating layer placed on the fourth surface, the side surface of the second through hole, the side surface of the first through hole, the side surface of the first opening portion, and the surface of the first conducting layer and a surface of the first conducting layer exposed from the organic insulating layer by the second opening portion, wherein the side surface of the second through hole is a first tapered surface.

A vibrator device according to an aspect of the present disclosure includes the above described semiconductor device.

### BRIEF DESCRIPTION OF THE DRAWINGS

FIG. 1 is a perspective view schematically showing a vibrator device according to a first embodiment.

FIG. 2 is a plan view schematically showing the vibrator device according to the first embodiment.

FIG. 3 is a sectional view schematically showing the vibrator device according to the first embodiment.

FIG. 4 is a sectional view schematically showing a semiconductor device.

FIG. 5 is a flowchart showing an example of a manufacturing method for the semiconductor device.

FIG. 6 is a sectional view schematically showing a manufacturing step of the semiconductor device.

FIG. 7 is a sectional view schematically showing a manufacturing step of the semiconductor device.

FIG. 8 is a sectional view schematically showing a manufacturing step of the semiconductor device.

FIG. 9 is a sectional view schematically showing a manufacturing step of the semiconductor device.

FIG. 10 is a sectional view schematically showing a manufacturing step of the semiconductor device.

FIG. 11 is a sectional view schematically showing a manufacturing step of the semiconductor device.

FIG. 12 is a sectional view schematically showing a manufacturing step of the semiconductor device.

FIG. 13 is a sectional view schematically showing a manufacturing step of the semiconductor device.

FIG. 14 is a sectional view schematically showing a semiconductor device according to a first modified example.

FIG. 15 is a sectional view schematically showing a semiconductor device according to a second modified example.

FIG. 16 is a sectional view schematically showing a semiconductor device of a vibrator device according to a second embodiment.

### DESCRIPTION OF EMBODIMENTS

As below, preferred embodiments of the present disclosure will be explained in detail using the drawings. Note that the embodiments to be described do not unduly limit the present disclosure described in What is Claimed is. Further, not all configurations to be described are necessarily essential elements of the present disclosure.

### 1. First Embodiment

### 1.1. Vibrator Device

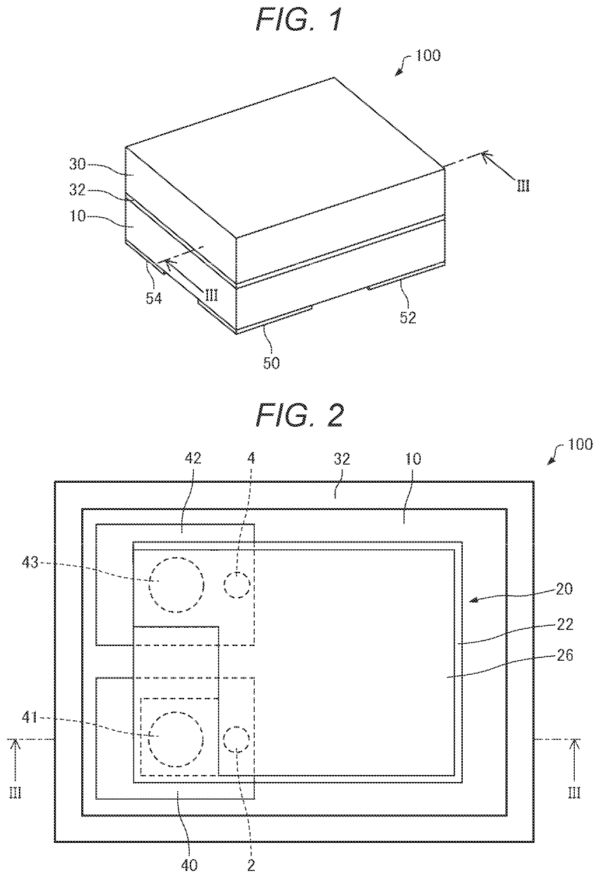

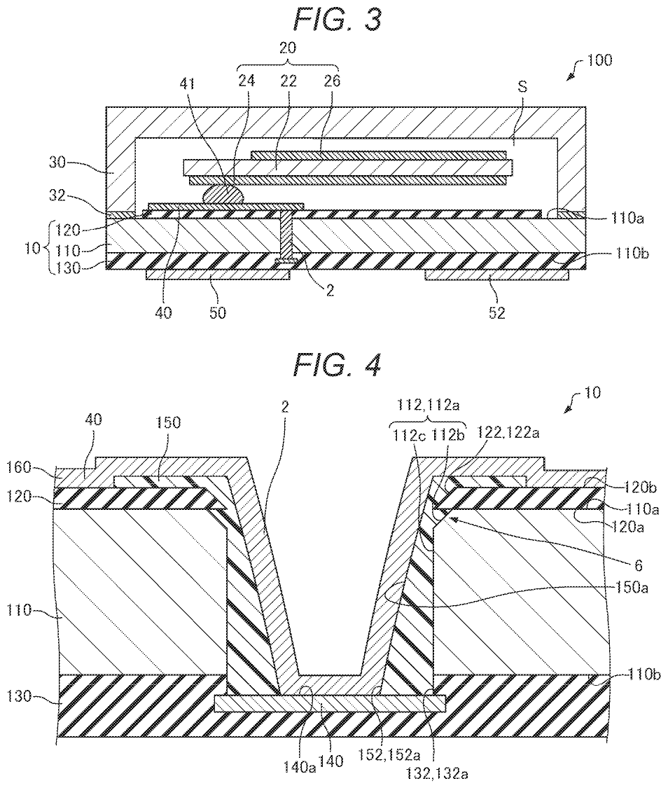

First, a vibrator device according to a first embodiment will be explained with reference to the drawings. FIG. 1 is a perspective view schematically showing a vibrator device 100 according to the first embodiment. FIG. 2 is a plan view schematically showing the vibrator device 100 according to the first embodiment. FIG. 3 is a sectional view schematically showing the vibrator device 100 according to the first embodiment. Note that FIG. 3 is the sectional view along lines III-III in FIGS. 1 and 2.

As shown in FIGS. 1 to 3, the vibrator device 100 includes a semiconductor device 10, a vibrator element 20, and a lid member 30. Note that, in FIG. 2, for convenience, the illustration of the lid member 30 is omitted. Further, in FIG. 3, the semiconductor device 10 is simplified.

The semiconductor device 10 includes a semiconductor substrate 110, a first insulating layer 120, and a second insulating layer 130. The semiconductor substrate 110 has a first surface 110a and a second surface 110b having a front-back relation to the first surface 110a. The semiconductor substrate 110 is e.g., a silicon substrate. The semiconductor substrate 110 is not limited to the silicon substrate, but may be a germanium substrate, a gallium nitride substrate, or the like.

The semiconductor substrate 110 includes an oscillation circuit oscillating the vibrator element 20. The oscillation circuit is placed on the second surface 110b of the semiconductor substrate 110. Though not illustrated, circuit elements including a transistor and a diode forming the oscillation circuit are formed on the second surface 110b of the semiconductor substrate 110.

For example, the oscillation circuit generates a frequency of a reference signal such as a clock signal by oscillating the vibrator element 20. The vibrator device 100 includes the oscillation circuit, and thereby, the vibrator device 100 may be used as a quartz crystal oscillator. Note that the semiconductor device 10 does not necessarily include the oscillation circuit and, in this case, the vibrator device 100 may be used as a quartz crystal vibrator. Note that the semiconductor substrate 110 may include a temperature compensated circuit correcting vibration characteristics of the vibrator element 20 according to temperature changes.

The first insulating layer 120 is placed on the first surface 110a of the semiconductor substrate 110. The material of the first insulating layer 120 is e.g., silicon oxide. The second insulating layer 130 is placed on the second surface 110b of the semiconductor substrate 110. The second insulating layer 130 covers the circuit elements formed on the second surface 110b of the semiconductor substrate 110. Though not illustrated, a plurality of wires and a plurality of pads are provided on the second insulating layer 130. The second insulating layer 130 is an interlayer insulating film. The material of the second insulating layer 130 is e.g., silicon oxide. Note that the materials of the first insulating layer 120 and the second insulating layer 130 are not limited to silicon oxide, but may be an insulating material such as silicon nitride.

In the semiconductor device 10, a first through electrode 2 and a second through electrode 4 penetrating the first insulating layer 120 and the semiconductor substrate 110 are formed.

The vibrator element 20 is placed on the first surface 110a of the semiconductor substrate 110. The vibrator element 20 is e.g., a piezoelectric-drive vibrator element. The vibrator element 20 includes e.g., an element substrate 22, a first excitation electrode 24, and a second excitation electrode 26. The element substrate 22 is e.g., a quartz crystal substrate. The element substrate 22 is e.g., an AT cut quartz crystal substrate vibrating in a thickness-shear vibration mode. Note that the element substrate 22 is not limited to the AT cut quartz crystal substrate, but may be another quartz crystal substrate than the AT cut quartz crystal substrate e.g., an X cut quartz crystal substrate, a Y cut quartz crystal substrate, a Z cut quartz crystal substrate, a BT cut quartz crystal substrate, an SC cut quartz crystal substrate, or an ST cut quartz crystal substrate.

The material of the element substrate 22 is not limited to quartz crystal, but may be piezoelectric single crystal such as lithium niobate, lithium tantalate, lithium tetraborate, langasite, potassium niobate, or gallium phosphate or another piezoelectric single crystal. Further, for example, the vibrator element 20 may be the so-called MEMS (Micro Electro Mechanical Systems) vibrator element formed by placement of a piezoelectric film and electrodes on a substrate such as a silicon substrate.

The first excitation electrode 24 and the second excitation electrode 26 are respectively placed on two surfaces having a front-back relation of the element substrate 22. The materials of the first excitation electrode 24 and the second excitation electrode 26 are e.g., metal materials such as gold, silver, platinum, palladium, iridium, copper, aluminum, nickel, chromium, titanium, or tungsten, or alloys containing these metal materials.

Note that the vibrator element 20 is not limited to the piezoelectric-drive vibrator element, but may be an electrostatic-drive vibrator element using electrostatic force, a tuning fork-type vibrator element having a plurality of vibrating arms flexurally vibrating in in-plane directions, a tuning fork-type vibrator element having a plurality of vibrating arms flexurally vibrating in out-of-plane directions, a gyro sensor element having a drive-vibrating drive arm and a detection-vibrating detection arm and detecting an angular velocity, or an acceleration sensor element having a detection portion detecting an acceleration.

The lid member 30 is placed on the first surface 110a of the semiconductor substrate 110. The lid member 30 is formed using e.g., a silicon substrate. The lid member 30 forms a cavity S as a space housing the vibrator element 20 with the semiconductor substrate 110. The lid member 30 has a recessed portion for forming the cavity S. The cavity S is a space air-tightly sealed by the semiconductor substrate 110 and the lid member 30. The semiconductor substrate 110 on which the oscillation circuit is formed configures a part of a package forming the cavity S, and reduction in thickness and size may be realized in the vibrator device 100.

The lid member 30 is joined to the first surface 110a of the semiconductor substrate 110 via a joint layer 32. The lid member 30 and the semiconductor substrate 110 are joined by activated bonding via the joint layer 32. The joint layer 32 is e.g., a gold layer having a thickness of about 100 nm. Note that the material of the joint layer 32 is not limited to gold, but copper, aluminum, or the like may be used. Or, the semiconductor substrate 110 of silicon and the lid member 30 of silicon may be activated and directly bonded.

The activated bonding refers to a method of activating the surface of the joint layer 32 by irradiating the joint layer 32 with an energy beam of argon gas or the like, and then, bonding the lid member 30 and the semiconductor substrate 110 via the joint layer 32. According to the activated bonding, bonding is performed by diffusion and reorganization of gold atoms on a contact surface, and strong bonding without a bonded interface is performed. Further, the surface of the joint layer 32 is smoothed, and thereby, bonding may be performed only by free surface energy of the surface of the joint layer 32 and bonding may be performed at normal temperature without aggressive pressurization.

A first mount electrode 40 and a second mount electrode 42 are provided on the first surface 110a of the semiconductor substrate 110 via the first insulating layer 120. The first mount electrode 40 is electrically coupled to the first excitation electrode 24 of the vibrator element 20 via a first conducting joint member 41. The second mount electrode 42 is electrically coupled to the second excitation electrode 26 of the vibrator element 20 via a second conducting joint member 43.

The first conducting joint member 41 and the second conducting joint member 43 support the vibrator element 20. The first conducting joint member 41 and the second conducting joint member 43 include e.g., metal bumps such as gold bumps and solder bumps and resin adhesives formed by dispersion of conducting fillers.

The first mount electrode 40 is electrically coupled to the oscillation circuit placed on the second surface 110b of the semiconductor substrate 110 via the first through electrode 2. The second mount electrode 42 is electrically coupled to the oscillation circuit placed on the second surface 110b of the semiconductor substrate 110 via the second through electrode 4. Therefore, the first excitation electrode 24 of the vibrator element 20 is electrically coupled to the oscillation circuit via the first conducting joint member 41, the first mount electrode 40, and the first through electrode 2. The second excitation electrode 26 of the vibrator element 20 is electrically coupled to the oscillation circuit via the second conducting joint member 43, the second mount electrode 42, and the second through electrode 4.

The oscillation circuit is electrically coupled to a first external coupling terminal 50, a second external coupling terminal 52, and a third external coupling terminal 54 placed on the surface of the second insulating layer 130. The first external coupling terminal 50 is e.g., a power supply external terminal electrically coupled to the oscillation circuit. The second external coupling terminal 52 is e.g., a ground external terminal. The third external coupling terminal 54 is e.g., an oscillation output external terminal. The oscillation circuit is driven by power supplied from the outside via the first external coupling terminal 50 as the power supply external terminal, oscillates the vibrator element 20 and generates an oscillation signal, and outputs the oscillation signal to the outside via the third external coupling terminal 54 as the oscillation output external terminal.

### 1.2. Semiconductor Device

Next, the semiconductor device 10 is explained. FIG. 4 is a sectional view schematically showing the semiconductor device 10. FIG. 4 corresponds to FIG. 3. As described above, the semiconductor device 10 includes the semiconductor substrate 110, the first insulating layer 120, and the second insulating layer 130. The semiconductor device 10 further includes a first conducting layer 140, an organic insulating layer 150, and a second conducting layer 160.

A first through hole 112 penetrating from the first surface 110a to the second surface 110b is formed in the semiconductor substrate 110. A side surface 112a of the first through hole 112, i.e., a side surface of the semiconductor substrate 110 defining the first through hole 112 is covered by the organic insulating layer 150.

The first insulating layer 120 has a third surface 120a at the semiconductor substrate 110 side and a fourth surface 120b having a front-back relation to the third surface 120a. A second through hole 122 penetrating from the fourth surface 120b to the third surface 120a is formed in the first insulating layer 120. The second through hole 122 is formed in a position overlapping with the first through hole 112 as seen from a direction along the normal line of the first surface 110a of the semiconductor substrate 110. The first through hole 112 and the second through hole 122 communicate with each other. A side surface 122a of the second through hole 122, i.e., a side surface of the first insulating layer 120 defining the second through hole 122 is covered by the organic insulating layer 150.

The side surface 112a of the second through hole 122 as a first tapered surface is a tapered surface. The side surface 122a of the second through hole 122 is inclined relative to the third surface 120a and the fourth surface 120b of the first insulating layer 120. The side surface 122a of the second through hole 122 is the tapered surface, and thereby, the second through hole 122 has a diameter smaller from an opening at the fourth surface 120b side of the second through hole 122 toward an opening at the third surface 120a side of the second through hole 122.

The side surface 112a of the first through hole 112 has a second tapered surface 112b and a perpendicular surface 112c. The second tapered surface 112b is formed in an end portion at the first surface 110a side of the semiconductor substrate 110. The second tapered surface 112b is inclined relative to the first surface 110a. The portion defined by the second tapered surface 112b of the first through hole 112 has a diameter smaller from an opening at the first surface 110a side of the first through hole 112 toward an opening at the second surface 110b side of the first through hole 112.

As shown in FIG. 4, the perpendicular surface 112c is a surface perpendicular to the second surface 110b of the semiconductor substrate 110. The perpendicular surface 112c couples the second tapered surface 112b and the second surface 110b of the semiconductor substrate 110. The perpendicular surface 112c and the second tapered surface 112b are continuous. A portion defined by the perpendicular surface 112c of the first through hole 112 has a fixed diameter.

The third surface 120a of the first insulating layer 120 and the second tapered surface 112b form a recessed portion 6. The recessed portion 6 is a space defined by the third surface 120a and the second tapered surface 112b. The recessed portion 6 is formed in a boundary part between the first insulating layer 120 and the semiconductor substrate 110. The recessed portion 6 is a recess formed in the side surface 112a of the first through hole 112. For example, the depth of the recessed portion 6 is from 1 μm to 4 μm. The organic insulating layer 150 is placed in the recessed portion 6. The organic insulating layer 150 is embedded in the recessed portion 6.

The second insulating layer 130 is placed on the second surface 110b of the semiconductor substrate 110. The first conducting layer 140 is provided in the second insulating layer 130. In the second insulating layer 130, a first opening portion 132 is formed. The first opening portion 132 is formed in the second insulating layer 130, and thereby, a surface 140a of the first conducting layer 140 is exposed from the second insulating layer 130. That is, the first opening portion 132 is formed in the second insulating layer 130, and thereby, a part not covered by the second insulating layer 130 is formed on the surface 140a of the first conducting layer 140. The first opening portion 132 is placed in a position overlapping with the first through hole 112 as seen from the direction along the normal line of the first surface 110a of the semiconductor substrate 110. The first opening portion 132 communicates with the first through hole 112. A side surface 132a of the first opening portion 132, i.e., a side surface of the second insulating layer 130 defining the first opening portion 132 is covered by the organic insulating layer 150.

The first conducting layer 140 is placed in the second insulating layer 130. The surface 140a of the first conducting layer 140 is exposed from the second insulating layer 130 by the first opening portion 132 formed in the second insulating layer 130. Further, the first conducting layer 140 is exposed from the organic insulating layer 150 by a second opening portion 152 formed in the organic insulating layer 150. The first conducting layer 140 is electrically coupled to the oscillation circuit formed on the semiconductor substrate 110 via wiring (not shown) provided in the second insulating layer 130. The first conducting layer 140 is e.g., an electrode pad for electrically coupling the oscillation circuit and the vibrator element 20. The material of the first conducting layer 140 is e.g., aluminum, copper, or the like.

The organic insulating layer 150 is placed on the fourth surface 120b of the first insulating layer 120, the side surface 122a of the second through hole 122, the side surface 112a of the first through hole 112, the side surface 132a of the first opening portion 132, and the surface 140a of the first conducting layer 140. The organic insulating layer 150 is e.g., a photosensitive resin. As the photosensitive resin, e.g., an epoxy resin, a polyimide resin, an acrylic resin, or the like may be used.

The second opening portion 152 is formed in the organic insulating layer 150. The second opening portion 152 is formed in the organic insulating layer 150, and thereby, the surface 140a of the first conducting layer 140 is exposed from the organic insulating layer 150. That is, the second opening portion 152 is formed in the organic insulating layer 150, and thereby, a part not covered by the organic insulating layer 150 is formed on the surface 140a of the first conducting layer 140. The second opening portion 152 overlaps with the first opening portion 132 as seen from the direction along the normal line of the first surface 110a of the semiconductor substrate 110. The second opening portion 152 is formed in the first opening portion 132.

The organic insulating layer 150 has a portion in a thickness larger from the opening at the first surface 110a side of the first through hole 112 toward the opening at the second surface 110b side of the first through hole 112. In the example shown in FIG. 4, the organic insulating layer 150 placed on the perpendicular surface 112c of the first through hole 112 has a thickness larger from the opening at the first surface 110a side of the first through hole 112 toward the opening at the second surface 110b side of the first through hole 112. The thickness of the organic insulating layer 150 in the first through hole 112 is the size of the organic insulating layer 150 in the normal direction of the side surface 112a of the first through hole 112.

The second conducting layer 160 is placed on a surface 150a of the organic insulating layer 150 and the surface 140a of the first conducting layer 140. The surface 150a of the organic insulating layer 150 is formed by the surface of the organic insulating layer 150 placed on the fourth surface 120b of the first insulating layer 120, the side surface 122a of the second through hole 122, the side surface 112a of the first through hole 112, the side surface 132a of the first opening portion 132, and the surface 140a of the first conducting layer 140. Though not illustrated, the second conducting layer 160 has a barrier layer and a metal layer stacked on the barrier layer. The material of the barrier layer is e.g., an alloy of titanium and tungsten. The material of the metal layer is e.g., copper or gold. Note that the material of the second conducting layer 160 is not limited to the above described example. For example, the second conducting layer 160 does not necessarily have the barrier layer.

The second conducting layer 160 functions as the first mount electrode 40 and the first through electrode 2. The first mount electrode 40 is formed by the second conducting layer 160 placed on the first surface 110a of the semiconductor substrate 110 via the first insulating layer 120. The first through electrode 2 is formed by the second conducting layer 160 placed on the side surface 122a of the second through hole 122, the side surface 112a of the first through hole 112, the side surface 132a of the first opening portion 132, and the surface 140a of the first conducting layer 140 via the organic insulating layer 150.

Note that the configuration of the second through electrode 4 is the same as the above described configuration of the first through electrode 2 shown in FIG. 4, and the explanation thereof will be omitted.

### 1.3. Manufacturing Method for Semiconductor Device

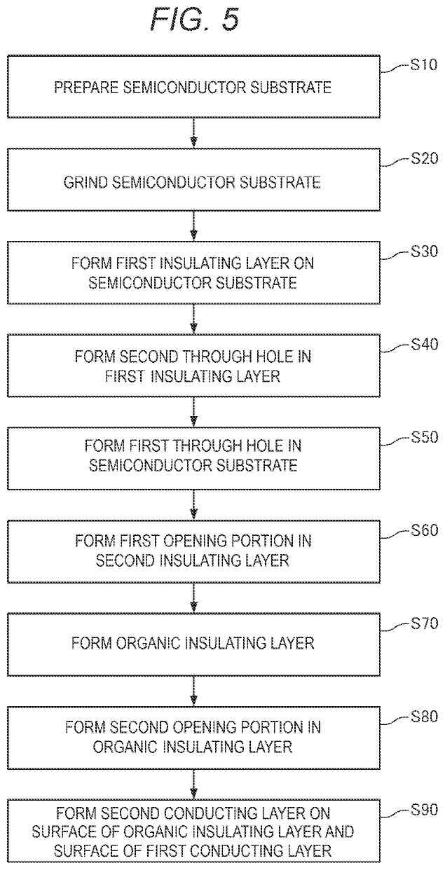

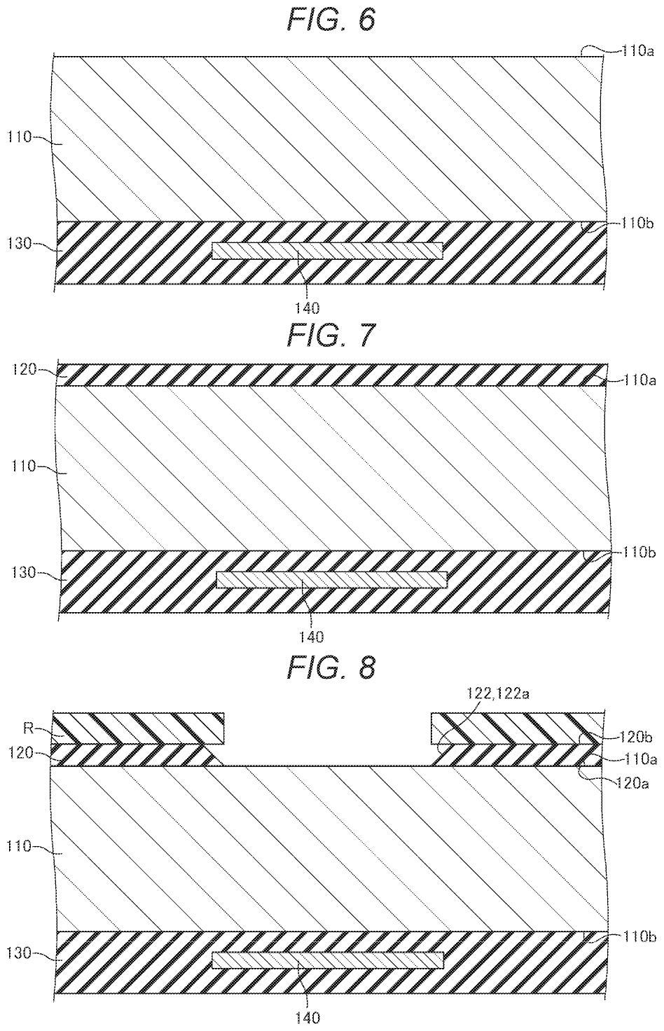

FIG. 5 is a flowchart showing an example of a manufacturing method for the semiconductor device 10. FIGS. 6 to 13 are sectional views schematically showing manufacturing steps of the semiconductor device 10. FIGS. 6 to 13 correspond to FIG. 4.

First, as shown in FIG. 6, the semiconductor substrate 110 with the second insulating layer 130 placed thereon is prepared (S10). The circuit elements forming the oscillation circuit are formed on the second surface 110b of the semiconductor substrate 110, and the second insulating layer 130 covers the circuit elements. In the second insulating layer 130, the first conducting layer 140 electrically coupled to the oscillation circuit is formed.

Then, the semiconductor substrate 110 is ground into a desired thickness (S20). For example, the semiconductor substrate 110 is ground to about 70 μm.

Then, as shown in FIG. 7, the first insulating layer 120 is formed on the first surface 110a of the semiconductor substrate 110 (S30). For example, the first insulating layer 120 as the silicon oxide layer may be deposited by CVD (Chemical Vapor Deposition). For example, the thickness of the first insulating layer 120 is about 1 μm.

Then, as shown in FIG. 8, the first insulating layer 120 is etched and the second through hole 122 penetrating from the fourth surface 120b to the third surface 120a of the first insulating layer 120 is formed (S40). Specifically, first, a resist layer R having an opening portion corresponding to the second through hole 122 is formed in the fourth surface 120b of the first insulating layer 120. Then, with the resist layer R as a mask, the first insulating layer 120 is etched. The etching of the first insulating layer 120 is performed by e.g., wet etching using a hydrofluoric acid etchant. Thereby, the first insulating layer 120 may be isotropically etched. The first insulating layer 120 is isotropically etched, and thereby, the side surface 122a of the second through hole 122 becomes the tapered surface inclined relative to the third surface 120a and the fourth surface 120b of the first insulating layer 120.

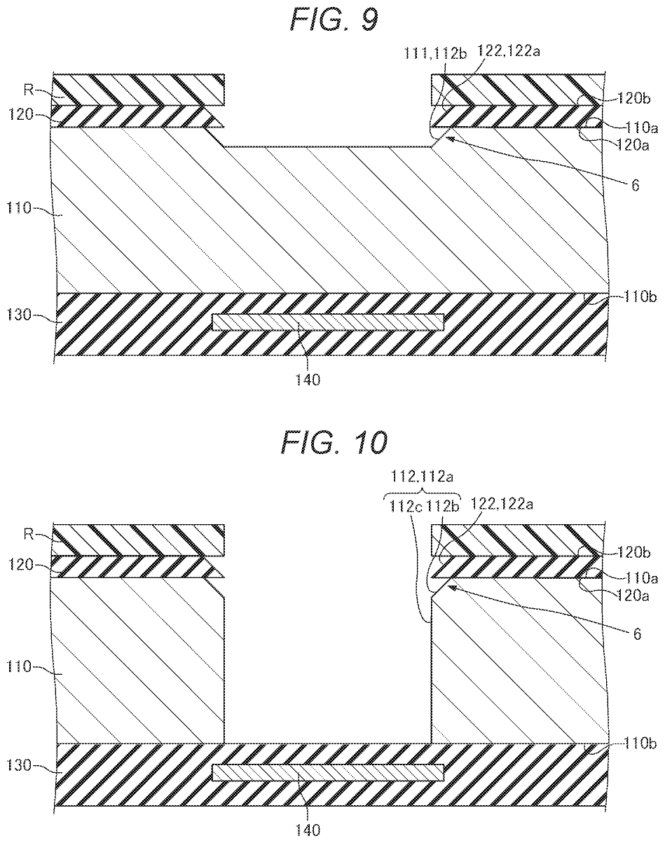

Then, as shown in FIG. 9, the semiconductor substrate 110 is etched and the first through hole 112 penetrating from the first surface 110a to the second surface 110b is formed in the semiconductor substrate 110 (S50).

Specifically, first, as shown in FIG. 9, with the resist layer R and the first insulating layer 120 as a mask, the semiconductor substrate 110 is isotropically etched. For example, the semiconductor substrate 110 as the silicon substrate is isotropically etched by dry etching. Thereby, the semiconductor substrate 110 is etched in a depth direction and also etched in a lateral direction, and a recessed portion 111 is formed in the semiconductor substrate 110. The semiconductor substrate 110 is isotropically etched, and thereby, the second tapered surface 112b inclined relative to the first surface 110a of the semiconductor substrate 110 is formed on a side surface of the recessed portion 111. Further, the recessed portion 6 is formed in the boundary part between the semiconductor substrate 110 and the first insulating layer 120 by the second tapered surface 112b and the third surface 120a of the first insulating layer 120.

Then, as shown in FIG. 10, with the resist layer R and the first insulating layer 120 as a mask, the semiconductor substrate 110 is anisotropically etched in the depth direction. For example, the semiconductor substrate 110 is anisotropically etched in the depth direction using the Bosch process. In the Bosch process, an etching step of etching the semiconductor substrate 110 with an etching gas and a deposition step of forming a protective film on the side surface 112a of the first through hole 112 are alternately performed. Accordingly, etching at a higher aspect ratio may be performed using the Bosch process. The etching of the semiconductor substrate 110 is performed to reach the second insulating layer 130 functioning as a stopper layer. As described above, the semiconductor substrate 110 is etched at two steps of the isotropic etching and anisotropic etching, and thereby, the first through hole 112 having the side surface 112a formed by the second tapered surface 112b and the perpendicular surface 112c may be formed.

Then, as shown in FIG. 11, with the resist layer R as a mask, the second insulating layer 130 is etched, and the first opening portion 132 is formed in the second insulating layer 130 (S60). The second insulating layer 130 as the silicon oxide layer may be etched by e.g., dry etching using CHF3 or CF4 or wet etching using a hydrofluoric acid etchant. The first opening portion 132 is formed to communicate with the first through hole 112. The first opening portion 132 is formed in the second insulating layer 130, and thereby, the surface 140a of the first conducting layer 140 is exposed. The second through hole 122, the first through hole 112, and the first opening portion 132 communicate with one another and forms one opening portion 7. The first opening portion 132 is formed in the second insulating layer 130, and then, the resist layer R is removed.

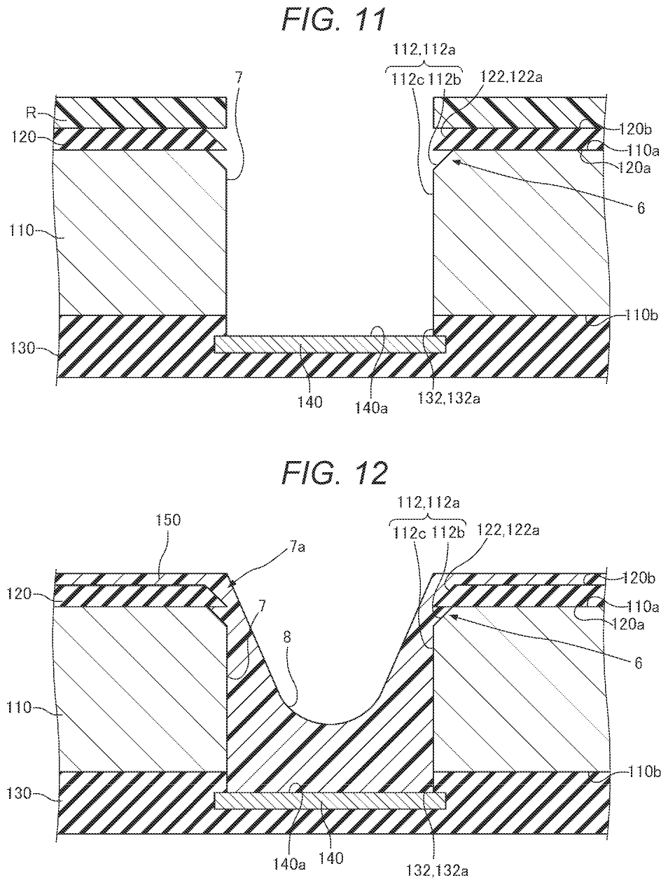

Then, as shown in FIG. 12, the organic insulating layer 150 is formed on the fourth surface 120b of the first insulating layer 120 and in the opening portion 7 (S70).

Specifically, first, as shown in FIG. 12, a solution containing a photosensitive resin material is applied to the fourth surface 120b of the first insulating layer 120 and in the opening portion 7 by spin coating. Here, the side surface 122a of the second through hole 122 is the tapered surface. Accordingly, in a corner part 7a of the opening portion 7, i.e., a corner part formed by the side surface 122a of the second through hole 122 and the fourth surface 120b of the first insulating layer 120, thinning of the thickness of the organic insulating layer 150 may be reduced. The side surface 122a of the second through hole 122 is formed as the tapered surface, and thereby, the corner part 7a of the opening portion 7 is chamfered. Accordingly, in the semiconductor device 10, for example, compared to a case where the corner part 7a of the opening portion 7 is at a right angle, the solution is attached more easily. Therefore, in the semiconductor device 10, thinning of the thickness of the organic insulating layer 150 may be reduced in the corner part 7a of the opening portion 7.

Further, the side surface 112a of the first through hole 112 has the second tapered surface 112b in an end portion at the first surface 110a side of the semiconductor substrate 110, and the third surface 120a of the first insulating layer 120 of the second tapered surface 112b form the recessed portion 6. The recessed portion 6 is formed in the boundary part between the first insulating layer 120 and the semiconductor substrate 110, and thereby, the solution containing the photosensitive resin material moves along the side surface 122a of the second through hole 122 into the recessed portion 6 and the solution is accumulated in the recessed portion 6. Accordingly, in the semiconductor device 10, for example, compared to a case where the recessed portion 6 is not formed in the boundary part between the first insulating layer 120 and the semiconductor substrate 110, thinning of the thickness of the organic insulating layer 150 may be reduced.

The solution containing the photosensitive resin material enters the opening portion 7, and a recessed portion 8 is formed in the opening portion 7 in the organic insulating layer 150.

Then, as shown in FIG. 13, the second opening portion 152 for exposing the first conducting layer 140 is formed in the organic insulating layer 150 (S80). Specifically, first, a portion corresponding to the second opening portion 152 of the organic insulating layer 150 is exposed to light. Then, the organic insulating layer 150 is developed. Thereby, the portion corresponding to the second opening portion 152 of the organic insulating layer 150 is removed and the second opening portion 152 is formed in the organic insulating layer 150. Note that, when the second opening portion 152 is formed in the organic insulating layer 150, the organic insulating layer 150 placed on the fourth surface 120b of the first insulating layer 120 may be patterned by exposure to light and development.

The organic insulating layer 150 is exposed to light and developed, and thereby, the shape of the recessed portion 8 of the organic insulating layer 150 shown in FIG. 12 is reflected on the organic insulating layer 150. Thereby, in the organic insulating layer 150, the portion in the thickness larger from the opening at the first surface 110a side of the first through hole 112 toward the opening at the second surface 110b side of the first through hole 112 is formed. Further, the light radiated from the first surface 110a side of the semiconductor substrate 110 to the organic insulating layer 150 is attenuated from the first surface 110a side toward the second surface 110b side of the semiconductor substrate 110. Furthermore, the light radiated from the first surface 110a side of the semiconductor substrate 110 to the organic insulating layer 150 is diffracted by a meniscus shape of the bottom surface of the recessed portion 8 shown in FIG. 12. By the light attenuation and light diffraction, the portion in the thickness larger from the opening at the first surface 110a side of the first through hole 112 toward the opening of the second surface 110b side of the first through hole 112 is formed in the developed organic insulating layer 150.

Here, the thickness of the organic insulating layer 150 is thinner, at the step of forming the second opening portion 152 in the organic insulating layer 150, a film loss that the thickness of the organic insulating layer 150 is reduced may occur and the first insulating layer 120 and the semiconductor substrate 110 may be exposed. The first insulating layer 120 and the semiconductor substrate 110 are exposed, and the coverage of the second conducting layer 160 becomes lower and causes disconnection of the second conducting layer 160. In the semiconductor device 10, as described above, thinning of the thickness of the organic insulating layer 150 may be reduced in the corner part 7a of the opening portion 7. Accordingly, at the step of forming the second opening portion 152 in the organic insulating layer 150, the probability that the first insulating layer 120 and the semiconductor substrate 110 are exposed may be reduced.

Note that the case where the organic insulating layer 150 is the positive photosensitive resin material is explained as above, however, the organic insulating layer 150 may be a negative photosensitive resin material. When the organic insulating layer 150 is a negative photosensitive resin material, the other part than the portion corresponding to the second opening portion 152 in the organic insulating layer 150 may be exposed to light.

Then, the organic insulating layer 150 is post-baked and the organic insulating layer 150 is cured.

Then, as shown in FIG. 4, the second conducting layer 160 is formed on the surface 150a of the organic insulating layer 150, the surface 140a of the first conducting layer 140 exposed from the organic insulating layer 150 by the second opening portion 152, and the fourth surface 120b of the first insulating layer 120 (S90). For example, the barrier layer of the alloy of titanium and tungsten is deposited by sputtering, then, the metal layer of copper is deposited by sputtering, the deposited barrier layer and metal layer are patterned, and thereby, the second conducting layer 160 may be formed. Note that the deposition method of the barrier layer and the metal layer is not limited to sputtering, but e.g., plating may be used.

Here, the organic insulating layer 150 has the portion in the thickness larger from the opening at the first surface 110a side of the first through hole 112 toward the opening at the second surface 110b side of the first through hole 112. Accordingly, in the first through hole 112, the surface 150a of the organic insulating layer 150 is the tapered surface inclined relative to the first surface 110a of the semiconductor substrate 110. Therefore, in the semiconductor device 10, for example, compared to a case where the surface 150a of the organic insulating layer 150 is perpendicular to the first surface 110a, the coverage of the second conducting layer 160 may be increased.

In the above described manner, the second conducting layer 160 functioning as the first through electrode 2 and the first mount electrode 40 may be formed. Note that the second through electrode 4 and the second mount electrode 42 may be manufactured in the same manner as the first through electrode 2 and the first mount electrode 40 and the explanation of the manufacturing method will be omitted.

Through the above described steps, the semiconductor device 10 may be manufactured.

### 1.4. Manufacturing Method for Vibrator Device

Next, a manufacturing method for the vibrator device 100 is explained. First, the semiconductor device 10 is manufactured using the above described manufacturing method. Then, as shown in FIGS. 2 and 3, the first conducting joint member 41 is formed on the first mount electrode 40 placed on the first surface 110a of the semiconductor substrate 110. Similarly, the second conducting joint member 43 is formed on the second mount electrode 42 placed on the first surface 110a of the semiconductor substrate 110.

Then, the vibrator element 20 is joined to the first conducting joint member 41 and the second conducting joint member 43. Here, the first excitation electrode 24 of the vibrator element 20 is electrically coupled to the first mount electrode 40 via the first conducting joint member 41. The second excitation electrode 26 of the vibrator element 20 is electrically coupled to the second mount electrode 42 via the second conducting joint member 43.

Then, the joint layer 32 is formed on the first surface 110a of the semiconductor substrate 110 and the semiconductor substrate 110 and the lid member 30 are joined by activated bonding via the joint layer 32. Thereby, the vibrator element 20 may be housed in the cavity S.

Through the above described steps, the vibrator device 100 may be manufactured.

### 1.5. Functions and Effects

In the semiconductor device 10, the side surface 122a of the second through hole 122 is the first tapered surface. Accordingly, in the semiconductor device 10, in the corner part formed by the side surface 122a of the second through hole 122 and the fourth surface 120b of the first insulating layer 120, i.e., the corner part 7a of the opening portion 7, thinning of the thickness of the organic insulating layer 150 may be reduced. Therefore, in the semiconductor device 10, the insulation between the semiconductor substrate 110 and the second conducting layer 160 may be increased and the reliability of the first through electrode 2 may be increased.

In the semiconductor device 10, the side surface 112a of the first through hole 112 has the second tapered surface 112b in the end portion at the first surface 110a side of the semiconductor substrate 110. Further, the third surface 120a of the first insulating layer 120 and the second tapered surface 112b form the recessed portion 6, and the organic insulating layer 150 is placed in the recessed portion 6. As described above, in the semiconductor device 10, the recessed portion 6 is formed in the boundary part between the first insulating layer 120 and the semiconductor substrate 110, and thereby, thinning of the thickness of the organic insulating layer 150 may be reduced in the corner part 7a of the opening portion 7. Therefore, in the semiconductor device 10, the insulation between the semiconductor substrate 110 and the second conducting layer 160 may be increased and the reliability of the first through electrode 2 may be increased.

In the semiconductor device 10, the organic insulating layer 150 has the portion in the thickness larger from the opening at the first surface 110a side of the first through hole 112 toward the opening at the second surface 110b side of the first through hole 112. Accordingly, in the semiconductor device 10, in the first through hole 112, the surface 150a of the organic insulating layer 150 is the tapered surface inclined relative to the first surface 110a of the semiconductor substrate 110. Therefore, in the semiconductor device 10, compared to a case where the surface 150a of the organic insulating layer 150 is perpendicular to the first surface 110a, the coverage of the second conducting layer 160 placed on the surface 150a of the organic insulating layer 150 may be increased. Thereby, the electric resistance of the second conducting layer 160 may be reduced.

The vibrator device 100 includes the semiconductor device 10, the vibrator element 20, and the lid member 30. Further, in the vibrator device 100, the oscillation circuit oscillating the vibrator element 20 is formed on the second surface 110b of the semiconductor substrate 110. Furthermore, in the vibrator device 100, the vibrator element 20 placed on the first surface 110a of the semiconductor substrate 110 is coupled to the oscillation circuit via the second conducting layer 160 forming the first through electrode 2 and the first conducting layer 140. In the vibrator device 100, as described above, the reliability of the first through electrode 2 formed by the second conducting layer 160 may be increased, and the vibrator element 20 and the oscillation circuit may be reliably electrically coupled. Therefore, in the vibrator device 100, the reliability may be increased.

### 1.6. Modified Examples

### 1.6.1. First Modified Example

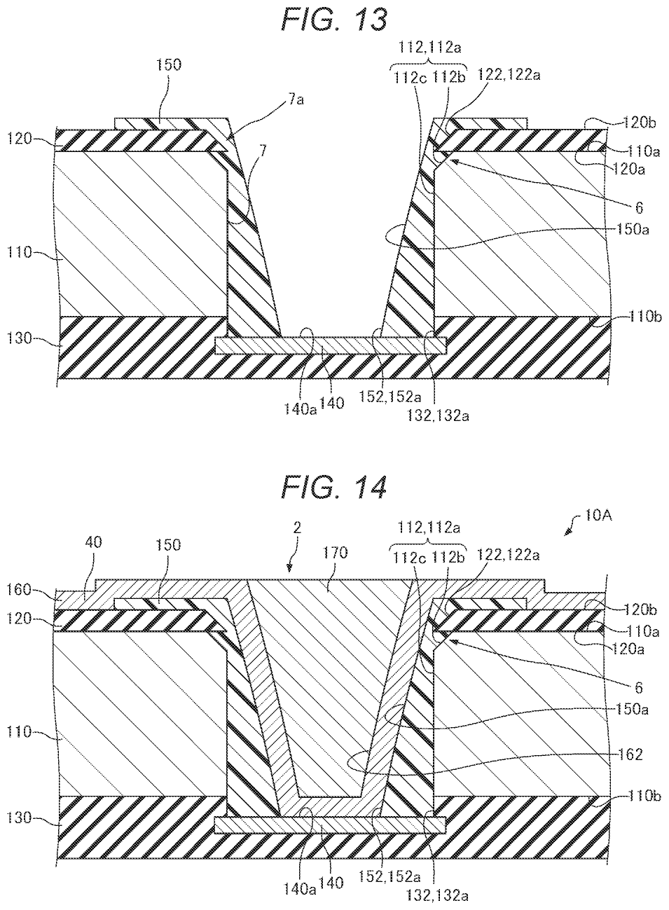

FIG. 14 is a sectional view schematically showing a semiconductor device 10A according to a first modified example. As below, in the semiconductor device 10A, the members having the same functions as the above described configuration members of the semiconductor device 10 shown in FIG. 4 have the same signs and the detailed explanation thereof will be omitted.

As shown in FIG. 14, in the semiconductor device 10A, a metal material 170 is embedded in a recessed portion 162 surrounded by the second conducting layer 160 placed in the first through hole 112. The metal material 170 is e.g., copper. Note that the metal material 170 is not particularly limited as long as the metal material has conductivity.

The metal material 170 may be embedded in the recessed portion 162 using e.g., printing of printing conducting paste or plating.

In the semiconductor device 10A, the same functions and effects as those of the semiconductor device 10 may be exerted. Further, in the semiconductor device 10A, the metal material 170 is embedded in the recessed portion 162 surrounded by the second conducting layer 160 placed in the first through hole 112. In the semiconductor device 10A, the second conducting layer 160 and the metal material 170 function as the first through electrode 2. Therefore, in the semiconductor device 10A, for example, compared to a case where the first through electrode 2 is formed by the second conducting layer 160 only, the reliability of the first through electrode 2 may be increased.

### 1.6.2. Second Modified Example

FIG. 15 is a sectional view schematically showing a semiconductor device 10B according to a second modified example. As below, in the semiconductor device 10B, the members having the same functions as the above described configuration members of the semiconductor device 10 shown in FIG. 4 have the same signs and the detailed explanation thereof will be omitted.

As shown in FIG. 15, in the semiconductor device 10B, the organic insulating layer 150 may have a portion in a fixed thickness in the direction from the opening at the first surface 110a side of the first through hole 112 toward the opening at the second surface 110b side of the first through hole 112.

The organic insulating layer 150 has a first portion 154 and a second portion 156. In the first portion 154, the thickness becomes larger from the opening at the first surface 110a side of the first through hole 112 toward the opening at the second surface 110b side of the first through hole 112. In the second portion 156, the thickness is fixed in the direction from the opening at the first surface 110a side of the first through hole 112 toward the opening at the second surface 110b side of the first through hole 112.

In the semiconductor device 10B, the same functions and effects as those of the semiconductor device 10 may be exerted.

### 2. Second Embodiment

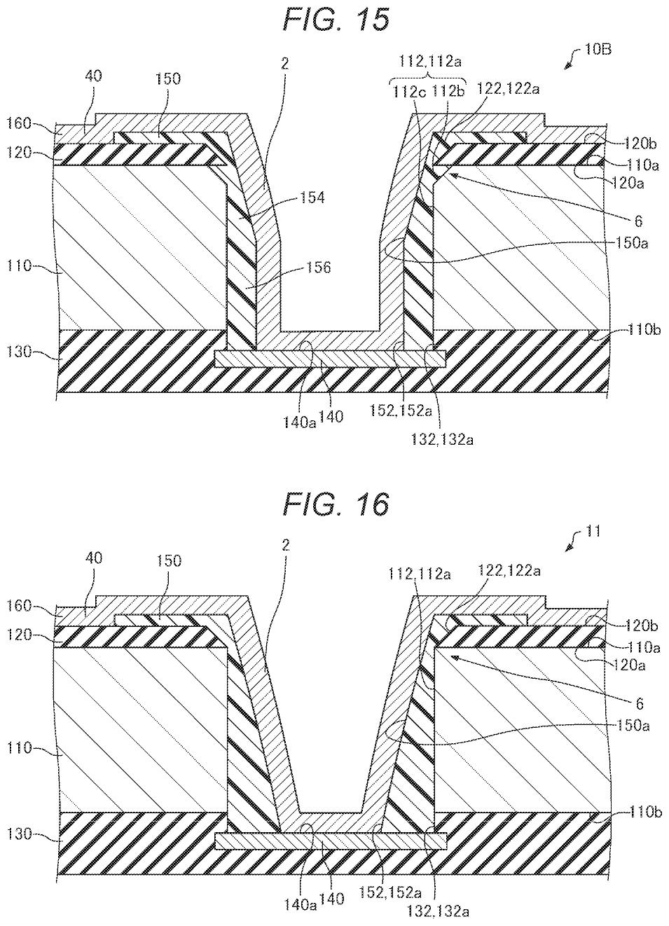

Next, a vibrator device according to a second embodiment will be explained. FIG. 16 is a sectional view schematically showing a semiconductor device 11 of the vibrator device according to the second embodiment. As below, in the semiconductor device 11, the members having the same functions as the above described configuration members of the semiconductor device 10 shown in FIG. 4 have the same signs and the detailed explanation thereof will be omitted.

As shown in FIG. 16, the semiconductor device 11 is different from the above described semiconductor device 10 shown in FIG. 4 in that the second tapered surface 112b is not formed on the side surface 112a of the first through hole 112. That is, in the semiconductor device 11, the recessed portion 6 is not formed in the end portion at the first surface 110a side of the semiconductor substrate 110. The side surface 112a of the first through hole 112 is formed by a surface perpendicular to the first surface 110a and the second surface 110b of the semiconductor substrate 110.

As shown in FIG. 16, in the semiconductor device 11, the side surface 122a of the second through hole 122 is the tapered surface. Accordingly, in the semiconductor device 11, for example, compared to a case where the side surface 122a of the second through hole 122 is perpendicular to the third surface 120a and the fourth surface 120b of the first insulating layer 120, thinning of the thickness of the organic insulating layer 150 may be reduced. Therefore, in the semiconductor device 11, thinning of the thickness of the organic insulating layer 150 may be reduced.

A manufacturing method for the semiconductor device 11 is the same as the above described manufacturing method for the semiconductor device 10 except that, at step S50 of forming the first through hole 112, the first through hole 112 is formed only by anisotropic etching, not by etching at the two steps, and the explanation thereof will be omitted.

Note that the above described embodiments and modified examples are just examples, and the present disclosure is not limited to those. For example, the respective embodiments and the respective modified examples can be appropriately combined.

The present disclosure is not limited to the above described embodiments, but various modifications can be further made. For example, the present disclosure includes substantially the same configurations as the configurations described in the embodiments. Substantially the same configurations refer to e.g., configurations having the same functions, methods, and results or configurations having the same purposes and effects. Further, the present disclosure includes configurations formed by replacement of non-essential parts of the configurations described in the embodiments. Furthermore, the present disclosure includes configurations that exert the same functions and effects or achieve the same purposes as those of the configurations described in the embodiments. Moreover, the present disclosure includes configurations formed by addition of techniques publicly known.

The following are derived from the above described embodiments and modified examples.

An aspect of a semiconductor device includes a semiconductor substrate including a first surface and a second surface having a front-back relation to the first surface, and having a first through hole formed to penetrate from the first surface to the second surface, a first insulating layer placed on the first surface, including a third surface at the semiconductor substrate side and a fourth surface having a front-back relation to the third surface, and having a second through hole formed in a position overlapping with the first through hole, a second insulating layer placed on the second surface and having a first opening portion formed in a position overlapping with the first through hole, a first conducting layer exposed from the second insulating layer by the first opening portion, an organic insulating layer placed on the fourth surface, a side surface of the second through hole, a side surface of the first through hole, a side surface of the first opening portion, and a surface of the first conducting layer, and having a second opening portion formed to overlap with the first opening portion, and a second conducting layer placed on a surface of the organic insulating layer placed on the fourth surface, the side surface of the second through hole, the side surface of the first through hole, the side surface of the first opening portion, and the surface of the first conducting layer and a surface of the first conducting layer exposed from the organic insulating layer by the second opening portion, wherein the side surface of the second through hole is a first tapered surface.

According to the semiconductor device, the side surface of the second through hole is the first tapered surface, and therefore, compared to a case where the side surface of the second through hole is perpendicular to the fourth surface of the first insulating layer, thinning of a thickness of the organic insulating layer may be reduced.

In the aspect of the semiconductor device, the side surface of the first through hole may have a second tapered surface in an end portion at the first surface side, the third surface and the second tapered surface may form a recessed portion, and the organic insulating layer may be placed in the recessed portion.

According to the semiconductor device, when the organic insulating layer is formed by application of a solution containing an organic insulating material, the solution moves along the side surface of the first through hole into the recessed portion and the solution is accumulated in the recessed portion, and therefore, thinning of the thickness of the organic insulating layer may be reduced.

In the aspect of the semiconductor device, the organic insulating layer may have a portion in a thickness larger from an opening at the first surface side of the first through hole toward an opening at the second surface side of the first through hole.

According to the semiconductor device, for example, compared to a case where the surface of the organic insulating layer is perpendicular to the first surface, the coverage of the second conducting layer placed on the surface of the organic insulating layer may be increased.

In the aspect of the semiconductor device, a metal material may be embedded in a recessed portion surrounded by the second conducting layer placed in the first through hole.

According to the semiconductor device, the second conducting layer and the metal material may function as a through electrode, and therefore, for example, compared to a case where the through electrode is formed by the second conducting layer only, the reliability of the through electrode may be increased.

An aspect of a vibrator device includes the above described semiconductor device, a vibrator element placed on the first surface, and a lid member joined to the first surface of the semiconductor substrate and forming a space housing the vibrator element, wherein an oscillation circuit oscillating the vibrator element is formed on the second surface of the semiconductor substrate, and the vibrator element is electrically coupled to the oscillation circuit via the second conducting layer and the first conducting layer.

In the vibrator device, the reliability of the through electrode formed by the second conducting layer may be increased, and therefore, the vibrator element and the oscillation circuit may be reliably electrically coupled.

What is claimed is:

1. A semiconductor device comprising:
a semiconductor substrate including a first surface and a second surface having a front-back relation to the first surface, and having a first through hole formed to penetrate from the first surface to the second surface;
a first insulating layer placed on the first surface, including a third surface at the semiconductor substrate side and a fourth surface having a front-back relation to the third surface, and having a second through hole formed in a position overlapping with the first through hole;
a second insulating layer placed on the second surface and having a first opening portion formed in a position overlapping with the first through hole;
a first conducting layer exposed from the second insulating layer by the first opening portion;
an organic insulating layer placed on the fourth surface, a side surface of the second through hole, a side surface of the first through hole, a side surface of the first opening portion, and a surface of the first conducting layer, and having a second opening portion formed to overlap with the first opening portion; and
a second conducting layer placed on a surface of the organic insulating layer placed on the fourth surface, the side surface of the second through hole, the side surface of the first through hole, the side surface of the first opening portion, and the surface of the first conducting layer and a surface of the first conducting layer exposed from the organic insulating layer by the second opening portion, wherein
the side surface of the second through hole is a first tapered surface.

2. The semiconductor device according to claim 1, wherein
the side surface of the first through hole has a second tapered surface in an end portion at the first surface side,
the third surface and the second tapered surface form a recessed portion, and
the organic insulating layer is placed in the recessed portion.

3. The semiconductor device according to claim 1, wherein
the organic insulating layer has a portion in a thickness larger from an opening at the first surface side of the first through hole toward an opening at the second surface side of the first through hole.

4. The semiconductor device according to claim 1, wherein
a metal material is embedded in a recessed portion surrounded by the second conducting layer placed in the first through hole.

5. A vibrator device comprising:
the semiconductor device according to claim 1;
a vibrator element placed on the first surface; and
a lid member joined to the first surface of the semiconductor substrate and forming a space housing the vibrator element, wherein
an oscillation circuit oscillating the vibrator element is formed on the second surface of the semiconductor substrate, and
the vibrator element is electrically coupled to the oscillation circuit via the second conducting layer and the first conducting layer.
